(19) United States
(12) Patent Application Publication
(10) Pub. No.: US 2016/0163829 A1
(43) Pub. Date: Jun. 9, 2016

(54) METHOD OF FORMING RECESS STRUCTURE

(71) Applicant: UNITED MICROELECTRONICS CORP., Hsin-Chu City (TW)

(72) Inventors: Kuan-Hsuan Ku, Tainan City (TW); Jhen-Cyuan Li, New Taipei City (TW); Shui-Yen Lu, Tainan City (TW)

(21) Appl. No.: 14/558,746

(22) Filed: Dec. 3, 2014

(51) Int. Cl. H01L 29/66; H01L 21/02; H01L 21/308; H01L 21/311; H01L 21/3065

(52) U.S. Cl. CPC H01L 29/66795; H01L 21/31144; H01L 21/31138; H01L 21/3065; H01L 21/3086; H01L 21/02529; H01L 21/02532

(57) ABSTRACT

The present invention is a method of forming a recess structure. First of all, a substrate is provided, and a first ARC layer is entirely formed on the substrate, covering a first region and a second region thereof. Then, the first ARC layer in the second region is etched with a CH-based gas. Then, a first removing process is performed to form a first recess in the second region. Next, a second ARC layer is entirely formed on the substrate, covering the first region and the second region. Then, the second ARC layer in the first region is etched, also with the CH-based gas, and the CH-based gas includes at least one of CH₄, C₂H₄, C₃H₆, CHF₃, CH₂F₂, and CH₃F. Finally, a second removing process is performed to form a second recess in the first region.

### BACKGROUND OF THE INVENTION

1. Field of the Invention

The present invention relates to a method of forming a recess structure, more particularly to a method of forming a recess structure in a fin field effect transistor (FinFET) structure.

2. Description of the Prior Art

As the semiconductor industry has progressed into nanometer technology process nodes in pursuit of higher device density and performance, challenges from currently fabrication speed up the development of non-planar field effect transistors (FETs), such as FinFET structures, which provide numerous advantages. Although existing methods for fabricating FinFET structures have been generally adequate for their intended purposes, as device scaling down continues, they have not been entirely satisfactory in all respects, however. Especially when the critical dimensions (CD) of the semiconductor circuits goes below than 14 nanometers, the current photoresist and lithography techniques are no longer qualified enough to support the fabricating process. For example, the deformation of photoresist patterns easily occurs during the etching process, and which may result in dimensional shift, thereby leading to serious defects to the semiconductor device.

### SUMMARY OF THE INVENTION

It is one of the primary objectives of the present invention to provide a method of forming a recess structure, in which a CH-based gas is utilized to gain improved CD bias control.

To achieve the purpose described above, the present invention provides a method of forming a recess structure, including following steps. First of all, a substrate is provided, wherein the substrate has a first region and a second region. Next, a first blocking layer and a first antireflective coating (ARC) layer are entirely formed on the substrate from bottom to top sequentially, wherein the first blocking layer and the first ARC layer cover the first region and the second region. Then, a first patterned photoresist layer is formed, wherein the first patterned photoresist layer covers the first region to expose a portion of the first ARC layer in the second region. After that, the portion of first ARC layer is etched, wherein a CH-based gas is provided when the first ARC layer is etched. Then, a first removing process is performed to form a first recess in the substrate of the second region. Next, a second blocking layer and a second ARC layer are entirely formed on the substrate from bottom to top sequentially, the second blocking layer and the second ARC layer cover the first region and the second region. Following this, a second patterned photoresist layer is formed, wherein the second patterned photoresist layer covers the second region to expose a portion of the second ARC layer in the first region. Then, the second ARC layer is etched, wherein the CH-based gas is provided when the second ARC layer is etched, and the CH-based gas includes at least one of CH₄, C₂H₄, C₃H₆, CHF₃, CH₂F₂, and CH₃F. Finally, a second removing process is performed to form a second recess in the substrate of the first region.

In the present invention, an antireflective coating (ARC) opening process is performed by using a CH-based gas, such as CH₄, C₂H₄, C₃H₆, CHF₃, CH₂F₂, and CH₃F, with the polymer generated by such CH-based gas to protect the etched sidewall, so as to avoid lateral over-etching issue, and to achieve the purpose of controlling the targeted critical dimension (CD).

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 10 are schematic diagrams illustrating a method of forming a recess structure according to a preferred embodiment of the present invention.

### DETAILED DESCRIPTION

In the following description, numerous specific details, as well as accompanying drawings, are given to provide a thorough understanding of the invention. It will, however, be apparent to one skilled in the art that the invention may be practiced without these specific details.

Referring to FIGS. 1-10, FIGS. 1-10 are schematic diagrams illustrating a method of forming a recess structure according to a preferred embodiment of the present invention, wherein FIGS. 1-2, and 7 are schematic top views illustrating the method in various forming steps, and FIGS. 3-6 and 8-10 are schematic cross-sectional views illustrating the method in various forming steps.

First of all, as shown in FIGS. 1-3, a substrate 100 having a plurality of fin structures 110 extending a long a direction Y is firstly provided, wherein the substrate 100 may include a semiconductor material, such as silicon, silicon germanium, silicon carbide, or silicon on insulator (SOI), but not limited thereto. The fin structures 110 may be formed by forming a patterned hard mask layer (not shown in the drawings) on the substrate 100, and then transferring the pattern of the patterned hard mask layer to the substrate 100 and forming the fin structures 110. In a preferably embodiment, a dielectric layer 102 is formed between the fin structures 110 to configure as shallow trench isolations (STIs) as shown in FIG. 1.

Precisely speaking, a plurality of gate structures 131 is formed across the fin structures 110, such that to define a plurality FinFET structures 130 on the substrate 100. Each of the FinFET structures 130 may further include a cap layer 133 and a spacer 135 surrounded the gate structure 131. In the present embodiment, the substrate 100 preferably has a first region A, a second region C, and a third region B between the first region A and the second region C. In the present embodiment, the FinFET structures 130 are preferably formed both in the first region A and the second region C of the substrate 100, and the FinFET structure 130a in the first region A may preferably have a first conductive type, such as P type and the FinFET structure 130c in the second region C may have a second conductive type, such as N type. However, Those skilled in the art would easily realize that the present invention is not limited to have the FinFET structures in different conductive types in the first region A and the second region C of the substrate 100 respectively, and in another embodiment, the FinFET structures formed in the first region and the second region may have the same conductive type, or the FinFET structures may optionally be formed only in the first region or the second region and a planar FET structure may be formed in other region.

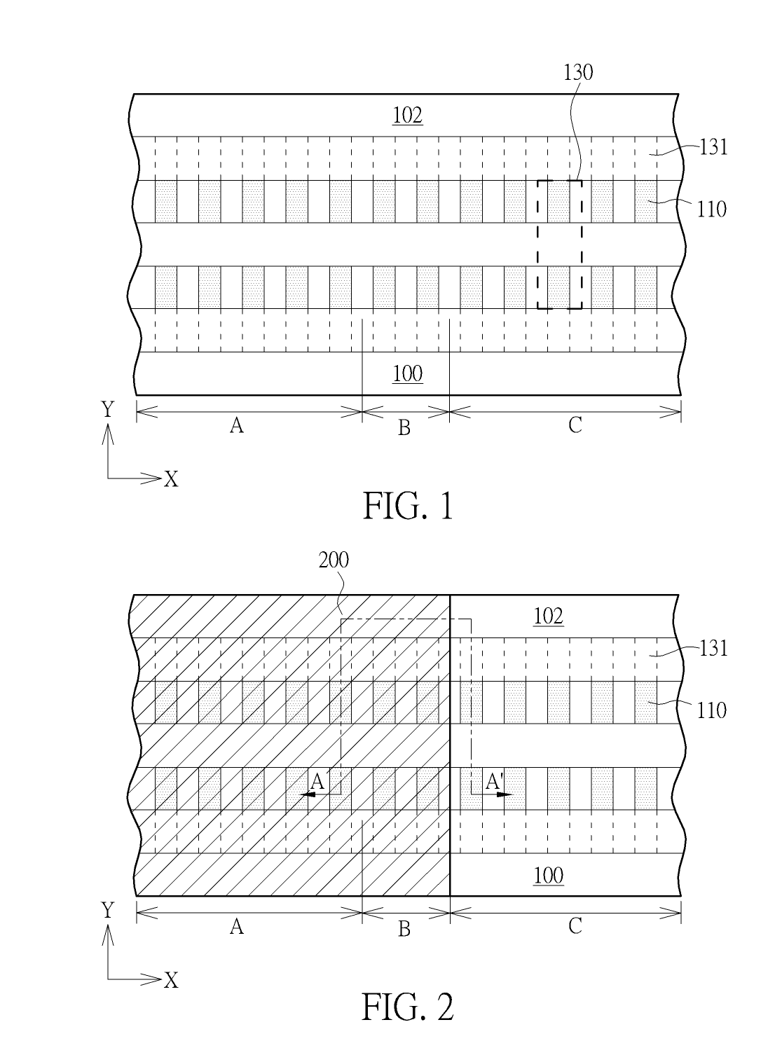

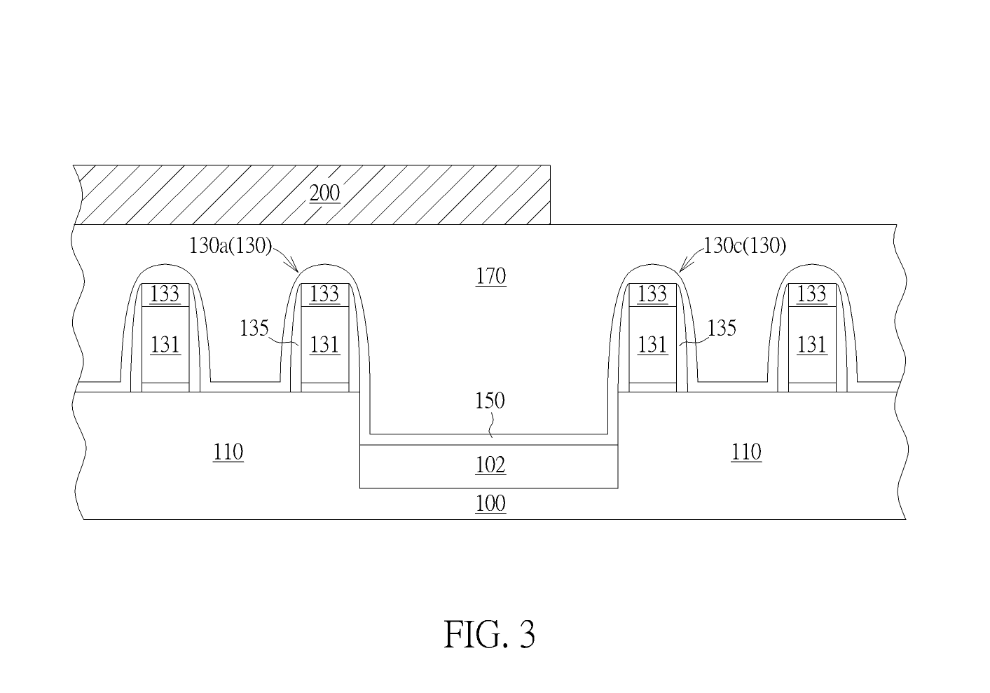

Following this, as shown in FIG. 2-3, FIG. 3 is a schematic cross-sectional views take along a cross line A-A′ in FIG. 2. A first blocking layer 150 and a first anti-reflective coating (ARC) layer 170 are entirely formed on the substrate 100 from bottom to top sequentially, covering the FinFET structures 130a formed on the first region A and the FinFET structures 130c formed on the second region C. The first blocking layer 150 and the first ARC layer 170 are formed through a chemical vapor deposition (CVD) process or a physical vapor deposition (PVD) process, wherein the first blocking layer 150 is preferably include a capping material having an etching selectivity related to the dielectric layer 102 and the fin structures 110, such as silicon nitride, and the first ARC layer 170 may include an organic bottom antireflective layer (BARC) composed of polyamides or polysulfones, but not limited thereto. In another embodiment, while the FinFET structures is formed only in one of the first region and the second region, the first blocking layer may include a capping material having an etching selectivity related to the dielectric layer, the fin structure in the one region and the substrate in the other region.

Next, further in view of FIGS. 2-3, a first patterned photoresist layer 200 is formed on the first ARC layer 170, for example, through directly forming a first photoresist layer (not shown in the drawings) entirely on the substrate 100, and then patterning the first photoresist layer, but not limited thereto. Please note that, the second region C is uncovered by the first patterned photoresist layer 200, which means that, the first patterned photoresist layer 200 covers the first region A and the third region B, such that, a portion of the first ARC layer 170 formed on the second region C is exposed from the first patterned photoresist layer 200, as shown in FIG. 2.

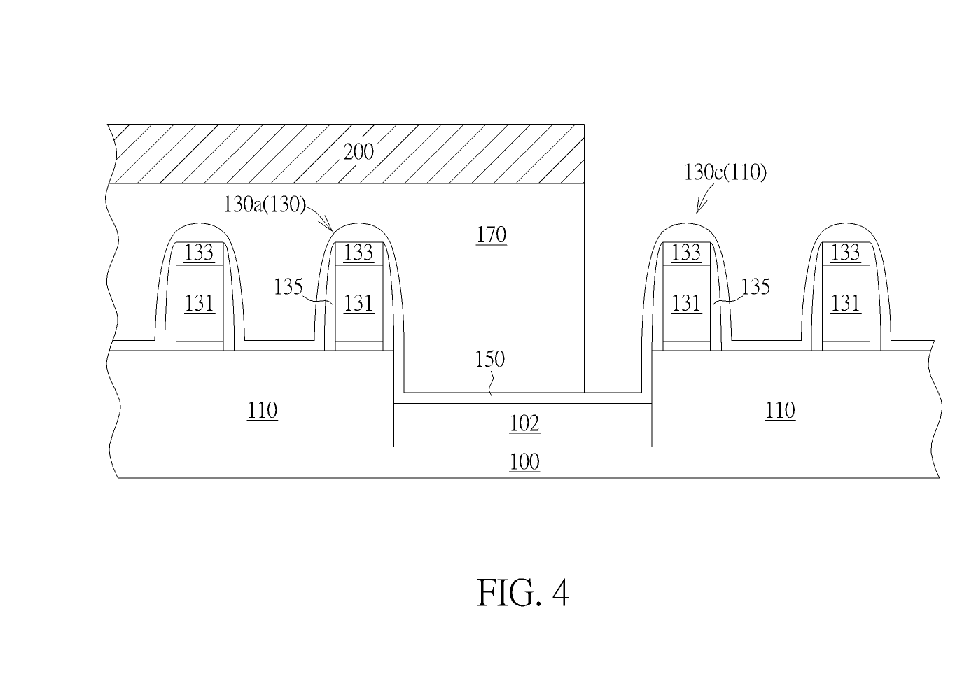

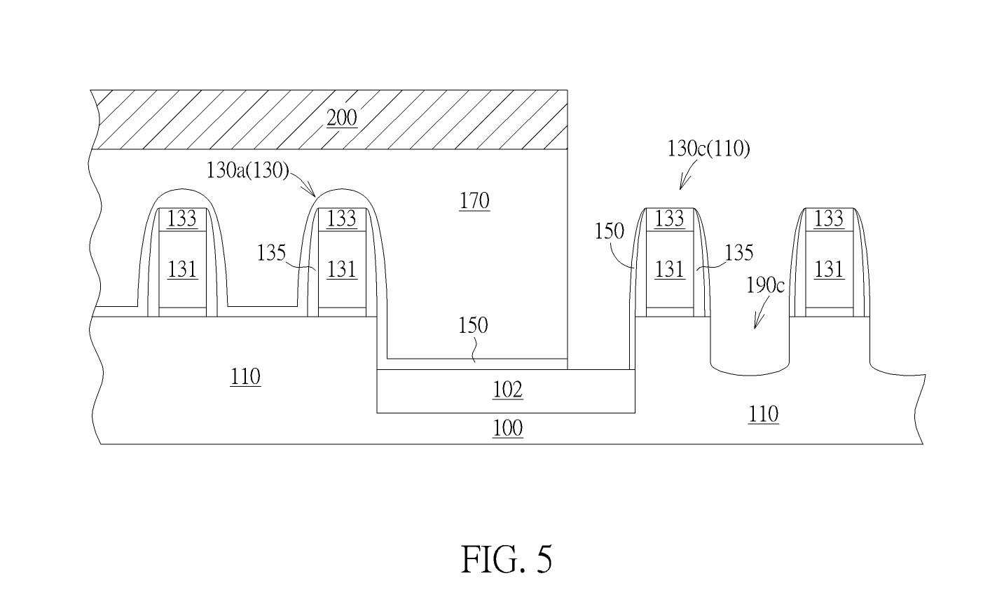

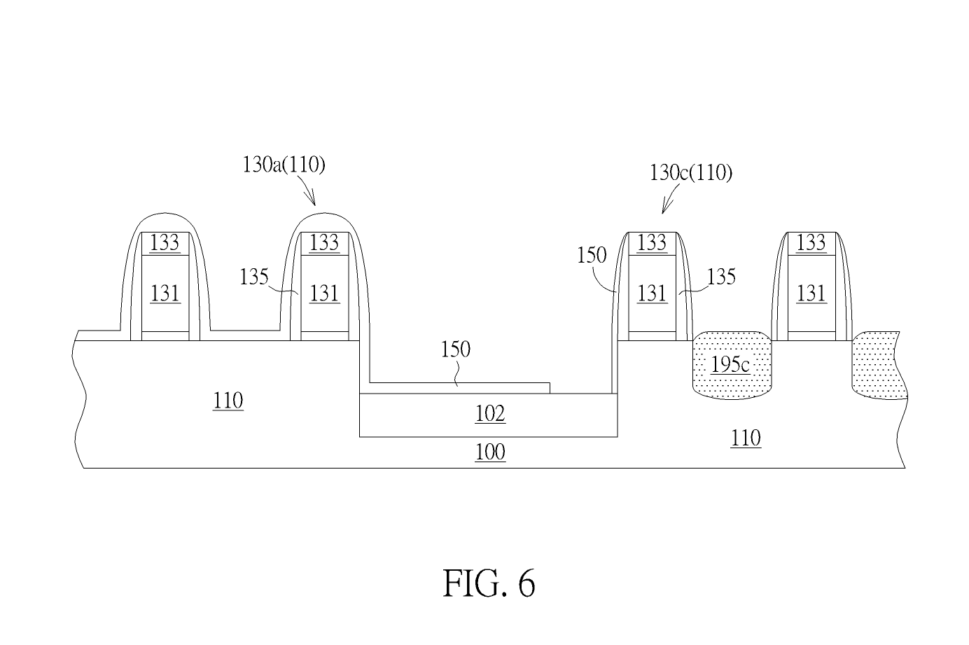

Then, as shown in FIGS. 4-5, a progressive removing process is performed to etch the exposed first ARC layer 170 and the first blocking layer 150 underneath sequentially. Precisely, the exposed first ARC layer 170 is etched by using an etchant, such as O₂, CO, CO₂, S-based gas or CH-based gas, so that the exposed first ARC layer 170 in the second region C is completed removed as shown in FIG. 4. In a preferably embodiment, the etchant includes the CH-based gas, such as CH₄, C₂H₄, C₃H₆, CHF₃, CH₂F₂, and CH₃F, with such CH-based gas maintaining the target patterned of the first patterned photoresist layer 200. Precisely speaking, the CH-based gas is easier to form polymer during the etching process, and such polymer may clog on the sidewall of etched first ARC layer 170 for protecting the etched first ARC layer 170, such that, the targeted critical dimension (CD) of ARC opening can be preferably controlled.

After that, as shown in FIG. 5, a removing process is performed, wherein the first blocking layer 150 under the exposed first ARC layer 170 is partially remove to expose the fin structures 110 in the second region C. The first blocking layer 150 is etched by using a first gas, which may include halogen, such as hydrogen bromide (HBr), hydrogen chloride (HCl), carbon tetrafluoride (CF₄), chlorine (Cl₂), bromine (Br₂), fluoromethane (CH₃F) or a combination thereof. In a preferably embodiment, the first gas may also include the CH-based gas, but not limited thereto. In a preferable embodiment, the first blocking layer 150 is etched through a two-step process, to progressively remove the first blocking layer 150 in the second region C, wherein different etching recipes or different etching ratio may be used in the two-step process, but the present invention is not limited thereto. Please note that, the first blocking layer 150 covered on the fin structures 110 in the second region C is completed removed to expose the fin structures 110 underneath, and a portion of the first blocking layer 150 covered on the FinFET structures 130c are remained however. Following this, the exposed fin structures 110 are then etched by using the remained first blocking layer 150 and the cap layer 133 as an etching mask to form a second recess 190c adjacent to the FinFET structures 130c. Precisely, the exposed fin structures 110 are etched for example by using a second gas, which may include the CH-based gas, halogen, such as hydrogen bromide (HBr), hydrogen chloride (HCl), carbon tetrafluoride (CF₄), chlorine (Cl₂), bromine (Br₂), fluoromethane (CH₃F) or a combination thereof, but the present invention is not limited thereto.

Then, as shown in FIG. 6, after completely removing the first patterned photoresist layer 200 and the remained first ARC layer 170, a selective epitaxial growth process is conducted to form an epitaxial structure 195c in the fin structure 110. The epitaxial structure 195c may include silicon carbon (SiC), but not limited thereto. Through the aforementioned steps, the FinFET structure 300c in the second region C is completely formed.

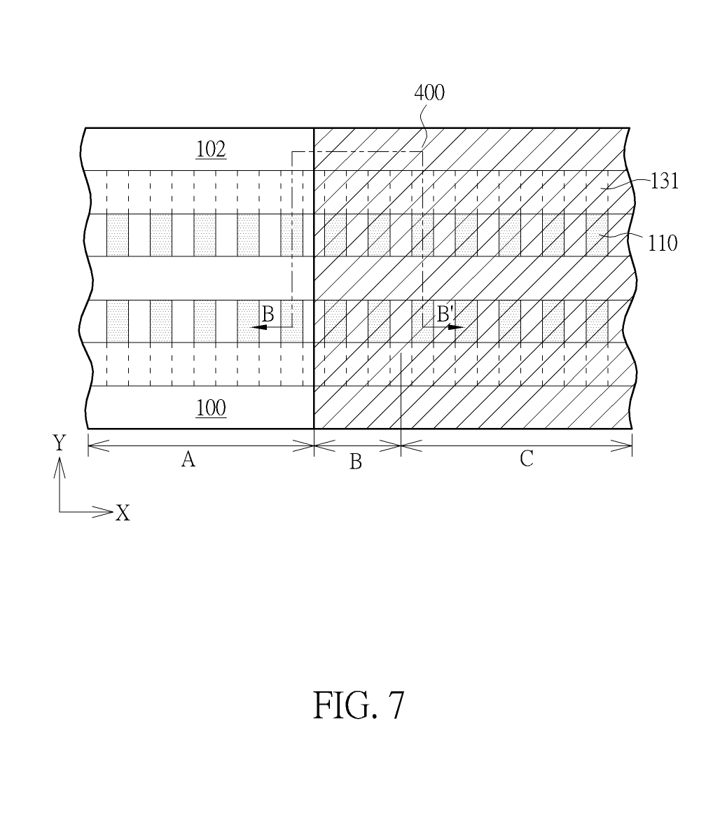

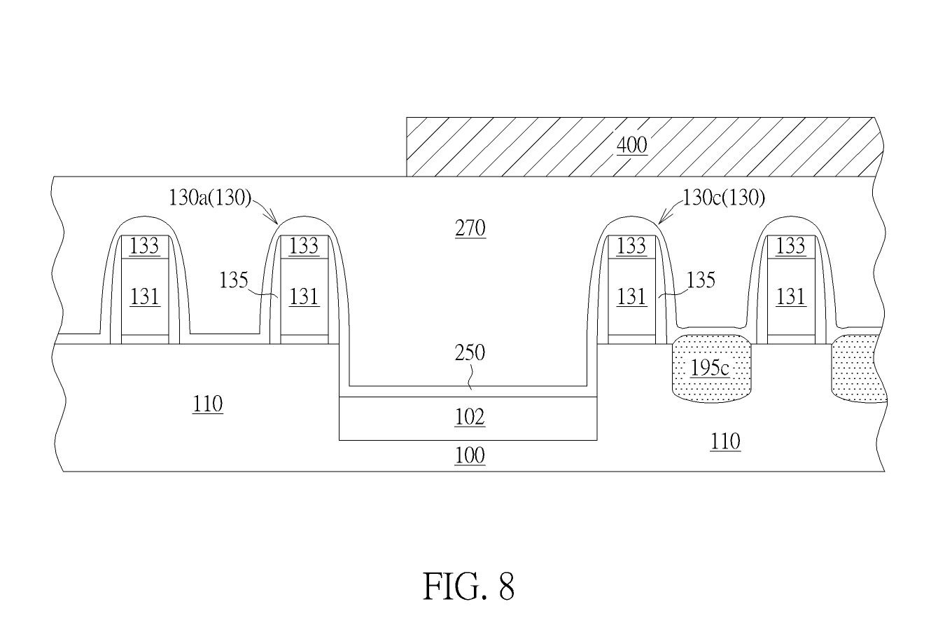

Next, as shown in FIGS. 7-8, FIG. 8 is a schematic cross-sectional views take along a cross line B-B′ in FIG. 7. After completely removing remained first blocking layer 150, a second blocking layer 250 and a second ARC layer 270 are also entirely formed on the substrate 100 from bottom to top, covering the FinFET structures 130a formed on the first region A and the FinFET structures 130c formed on the second region C. The second blocking layer 250 and the second ARC layer 270 are also formed through a CVD process or a PVD process. Please note that, since the second blocking layer 250 and the second ARC layer 270 are both formed through similar process and materials to that of the first blocking layer 150 and the second ARC layer 170, people in the art will be easy to realize that the property and the features of the second blocking layer 250 and the second ARC layer 270 may be similar to that of the first blocking layer 150 and the first ARC layer 170, and which will not be redundantly described herein.

Then, a second patterned photoresist layer 400 is formed on the second ARC layer 270, for example through similar process to the forming process of the first patterned photoresist layer 200, but not limited thereto. Please note that, the first region A is uncovered by the second patterned photoresist layer 400, which means that, the second patterned photoresist layer 400 covers the second region C and the third region B, such that, a portion of the second ARC layer 270 formed on the first region A is exposed from the second patterned photoresist layer 400, as shown in FIG. 7.

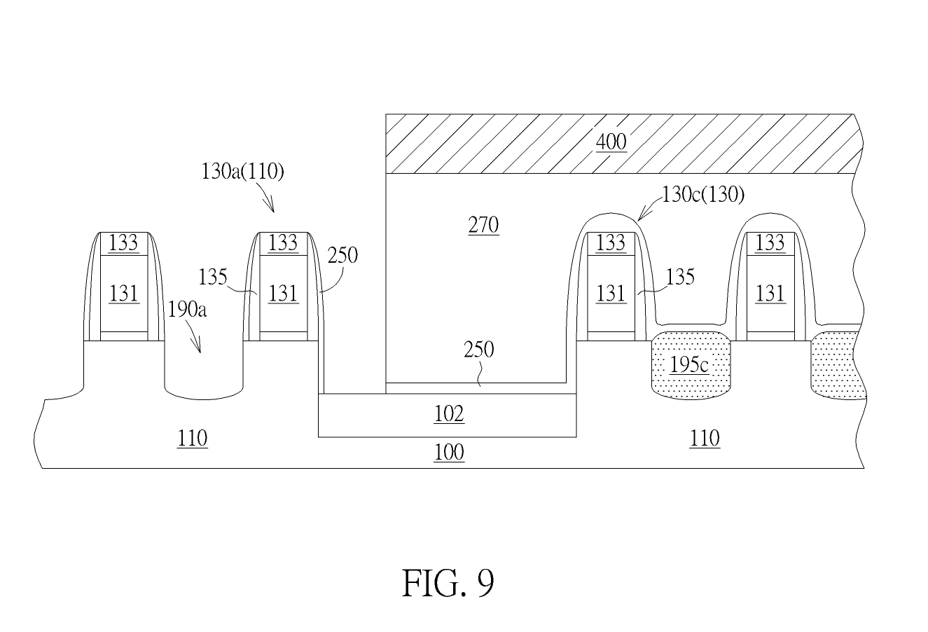

Then, as shown in FIGS. 9, another progressive removing process is performed to etch the exposed second ARC layer 270, and the second blocking layer 250 and a portion of the fin structure 110 underneath sequentially, and to form a second recess 190a. Likewise, the second ARC layer 270 is also etched by using the etchant, preferably for the CH-based gas, such as CH₄, C₂H₄, C₃H₆, CHF₃, CH₂F₂, and CH₃F, to completely remove the exposed second ARC layer 270. Then, the second blocking layer 250 is partially etched by using a third gas, which may include halogen, such as hydrogen bromide (HBr), hydrogen chloride (HCl), carbon tetrafluoride (CF₄), chlorine (Cl₂), bromine (Br₂), fluoromethane (CH₃F), the CH-based gas or a combination thereof, and the fin structure 110 may be etched by using a fourth gas including the CH-based gas, halogen, such as hydrogen bromide (HBr), hydrogen chloride (HCl), carbon tetrafluoride (CF₄), chlorine (Cl₂), bromine (Br₂), fluoromethane (CH₃F) or a combination thereof, but the present invention is not limited thereto. Please note that, since the exposed second ARC layer 270, the second blocking layer 250 and the fin structure 110 are etched sequentially through similar process carried on the first ARC layer 170, the first blocking layer 150 and the fin structures 110, those in the art will easy to realize that it is sufficient to obtain the second recess 190a adjacent the FinFET structure 130a also having similar property and features to that of first recess 190c in the present embodiment. However, the present invention is not limited thereto, and in another embodiment, the second recess may be formed in a manner to be different from that of the first recess, so as to form different typed second recess, such as having different shapes, different depths or different size from the first recess, for obtaining different electrically property.

It is worth mentioning that, since the exposed second region and the exposed first region are etched by using the etchant including the CH-based gas respectively, it is sufficient to maintain the target patterned of the photoresist layers during the two etching process. In other words, through using such CH-based gas to etch the ARC layers, the polymers generated by the CH-based gas will clog on the sidewall of etched ARC layers, so as to function as a sidewall protection layer. Thus, the targeted critical dimension (CD) of ARC opening can be preferably controlled in the present invention.

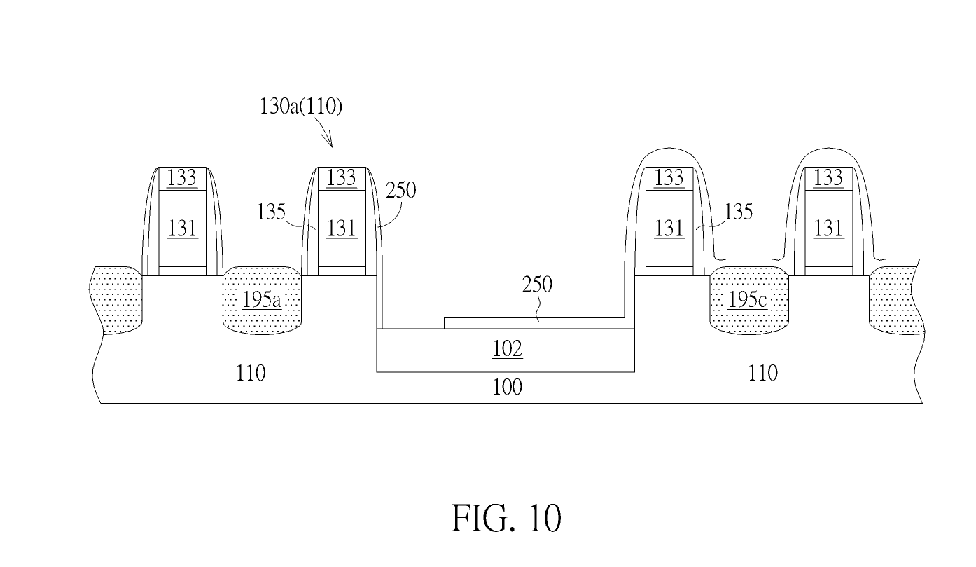

Finally, as shown in FIG. 10, after completely removing the second patterned photoresist layer 400, and the remained second ARC layer 270, another selective epitaxial growth process is conducted to form an epitaxial structure 195a in the second recess 190a in the fin structure 110. In the present embodiment, the epitaxial structure 195a may include silicon germanium (SiGe), but not limited thereto. In another embodiment, the epitaxial structure in the first region may include the same material (such as SiC or SiGe) in different concentrations or materials in the same conductive types to that of the epitaxial structure in the second region. Through the aforementioned steps, the FinFET structure 300a in the first region A is completely formed.

Through the present invention, the ARC opening process is performed by using the etchant preferably including the CH-based gas, with the polymer generated by such CH-based gas to protect the etched sidewall, so as to avoid lateral over-etching issue, and to achieve the purpose of controlling the targeted critical dimension (CD). In this way, based on the present invention, it is sufficient to form different type of FET structures in the first region and the second region separately. Although the aforementioned embodiment is exemplified on forming FinFET structures both in the two regions, but those in the art will easy to realize that the present invention is not limited to have the same or similar FinFET structure both in the two regions. In one embodiment, FinFET structures formed in the first region and the second region may have epitaxial structures in different conductive types, different shapes, different sizes or different composed materials to perform various electrically property. In another embodiment, the FinFET structures may also be optionally formed only in the first region or the second region, and a planar FET structure may be formed in other region.

Those skilled in the art will readily observe that numerous modifications and alterations of the device and method may be made while retaining the teachings of the invention. Accordingly, the above disclosure should be construed as limited only by the metes and bounds of the appended claims.

1. A method of forming a recess structure, comprising:
providing a substrate, having a first region and a second region;
forming a fin structure in the substrate;
entirely forming a first blocking layer and a first ARC layer from bottom to top sequentially on the substrate, the first blocking layer and the first ARC layer covering a gate structure across the fin structure in the first region and the second region;
forming a first patterned photoresist layer covered the first region to expose a portion of the first ARC layer in the second region;
etching the portion of the first ARC layer, wherein a CH-based gas is provided when etching the portion of the first ARC layer;
performing a first removing process to form a first recess in the substrate of the second region;
entirely forming a second blocking layer and a second ARC layer from bottom to top sequentially on the substrate, the second blocking layer and the second ARC layer covering the gate structure across the fin structure in the first region and the second region;
forming a second patterned photoresist layer covered the second region to expose a portion of the second ARC layer in the first region;
etching the portion of the second ARC layer, wherein the CH-based gas is provided when etching the portion of the second ARC layer in the first region; and
performing a second removing process to form a second recess in the substrate of the first region;
wherein the CH-based gas comprises at least one of CH₄, C₂H₄, and C₃H₆.

2. The method of forming the recess structure according to claim 1, wherein the fin structure is formed only in the substrate of the second region.

3. The method of forming the recess structure according to claim 2, wherein the first recess is formed in the fin structure, and the second recess is formed in the substrate of the first region.

4. The method of forming the recess structure according to claim 2, wherein the first removing process, further comprising:
providing a first gas to remove the first blocking layer on the substrate of the second region; and
providing a second gas to partially remove the substrate adjacent to the gate structure, to form the first recess.

5. The method of forming the recess structure according to claim 4, wherein the first gas comprises HBr, HCl, CF₄, Cl₂, Br₂, CH₃F, the CH-based gas or a composition thereof, and the second gas comprises the CH-based gas.

6. The method of forming the recess structure according to claim 1, wherein the fin structure is formed only in the substrate of the first region.

7. The method of forming the recess structure according to claim 6, wherein the second recess is formed in the fin structure, and the first recess is formed in the substrate of the second region.

8. The method of forming the recess structure according to claim 6, wherein the second removing process, further comprising:
providing a third gas to remove the second blocking layer on the substrate of the first region; and
providing a fourth gas to partially remove the substrate adjacent to the gate structure, to form the second recess.

9. The method of forming the recess structure according to claim 8, wherein the third gas comprises HBr, HCl, CF₄, Cl₂, Br₂, CH₃F, the CH-based gas or a composition thereof, and the fourth gas comprises the CH-based gas.

10. The method of forming the recess structure according to claim 1, further comprising:
performing a first selective epitaxial growing in the first recess, to form a first epitaxial structure; and
performing a second selective epitaxial growing in the second recess, to form a second epitaxial structure.

11. The method of forming the recess structure according to claim 10, wherein the performing of the first selective epitaxial growing is performed before the second blocking layer and the second ARC layer is formed.

12. The method of forming the recess structure according to claim 11, wherein the first epitaxial structure and the second epitaxial structure comprise different materials.

13. The method of forming the recess structure according to claim 12, wherein the first epitaxial structure and the second epitaxial structure comprise materials in different conductive types.

14. The method of forming the recess structure according to claim 13, the first epitaxial structure comprises SiC, and the second epitaxial structure comprises SiGe.

15. The method of forming the recess structure according to claim 12, wherein the first epitaxial structure and the second epitaxial structure comprise materials in a same conductive type.

16. The method of forming the recess structure according to claim 11, wherein the first epitaxial structure and the second epitaxial structure comprise a same material in different concentrations.

17. The method of forming the recess structure according to claim 16, wherein the first epitaxial structure and the second epitaxial structure comprise SiC or SiGe.

18. The method of forming the recess structure according to claim 1, wherein the first recess and the second recess are different in depths.

19. The method of forming the recess structure according to claim 1, wherein the first recess and the second recess are different in sizes.

20. The method of forming the recess structure according to claim 1, wherein the first recess and the second recess are different in shapes.
